(19) United States
(12) Patent Application Publication
(10) Pub. No.: US 2025/0181190 A1
(43) Pub. Date: Jun. 5, 2025

(54) ELECTRONIC DEVICE

(71) Applicant: KABUSHIKI KAISHA TOKAI RIKA DENKI SEISAKUSHO, Aichi (JP)

(72) Inventor: Ryoga SUZUKI, Aichi (JP)

(73) Assignee: KABUSHIKI KAISHA TOKAI RIKA DENKI SEISAKUSHO, Aichi (JP)

(21) Appl. No.: 18/851,420

(22) PCT Filed: Mar. 20, 2023
(86) PCT No.: PCT/JP2023/010971

§ 371 Date: Sep. 26, 2024

(30) Foreign Application Priority Data
Apr. 7, 2022 (JP) 2022-063766

(51) Int. Cl. G06F 3/041; G06F 3/044

(52) U.S. Cl. CPC G06F 3/04184; G06F 3/044; G06F 2203/04107

(57) ABSTRACT

An electronic device includes a positive electrode, a negative electrode, a conversion unit that converts electrical energy of a current flowing between the positive electrode and the negative electrode into other type of energy, a first current generation unit that generates and supplies a first current, which is to be the electrical energy of the conversion unit, a second current generation unit that generates a second current having a voltage greater than that of the first current to charge the positive electrode, and supplies the positive electrode with the second current superimposed on the first current, and a control unit that controls the second current to be superimposed on the first current by controlling the second current generation unit, and determines the approach or contact of the detection target based on a measurement result of a voltage of the positive electrode measured.

### CROSS-REFERENCE TO RELATED APPLICATIONS

The present patent application claims the priority of Japanese patent application No. 2022-063766 filed on Apr. 7, 2022, and the entire contents of Japanese patent application No. 2022-063766 are hereby incorporated by reference.

### TECHNICAL FIELD

The present invention relates to an electronic device.

### BACKGROUND ART

A passive matrix organic electroluminescent display is known which has a light-emitting function and a touch-detection function (see, e.g., PTL 1).

The passive matrix organic electroluminescent display includes an organic EL (Electro-Luminescence) element that has plural negative electrodes, plural positive electrodes, and an organic functional layer unit being sandwiched between the negative electrodes and the positive electrodes and including a light-emitting layer. The passive matrix organic electroluminescent display is configured such that the negative electrodes and the positive electrodes serve as touch detection electrodes, and the light-emitting period of the organic EL element and the touch-detection period by the touch detection electrodes are temporally separated, i.e., the light-emitting period and the touch-detection period alternate.

### CITATION LIST

### Patent Literatures

PTL 1: JP 2020-030884 A

### SUMMARY OF INVENTION

The passive matrix organic electroluminescent display disclosed in PTL 1 alternately switches between the light-emitting period and the touch-detection period, hence, the problem is that, as compared to when not switching, the light-emitting period is shorter which results in lower brightness, and also the touch-detection period is shorter which results in lower accuracy of touch operation detection. Another problem is that when, e.g., the organic functional layer converts electrical energy into energy other than light energy, electrical energy conversion is intermittent since the electrical energy conversion period and the touch-detection period alternate.

It is an object of the invention to provide an electronic device that detects a detection target while continuously converting electrical energy.

An electronic device in an embodiment of the invention comprises:
a positive electrode arranged below an operation input surface that a detection target approaches or comes into contact with;
a negative electrode electrically connected to the positive electrode;
a conversion unit that is electrically connected between the positive electrode and the negative electrode and converts electrical energy of a current flowing between the positive electrode and the negative electrode into other type of energy;
a current limiting unit that is electrically connected to the negative electrode and limits a current flowing through the negative electrode via the positive electrode and the conversion unit to a current limit value;
a first current generation unit that is electrically connected to the positive electrode, and generates and supplies a first current, which is to be the electrical energy of the conversion unit, to the positive electrode;
a second current generation unit that is electrically connected to the positive electrode, generates a second current having a voltage greater than that of the first current to charge the positive electrode, and supplies the positive electrode with the second current superimposed on the first current; and
a control unit that controls the second current to be superimposed on the first current by controlling the second current generation unit, and determines an approach or contact of the detection target based on a measurement result of a voltage of the positive electrode measured concurrently with the conversion of the electrical energy by the conversion unit.

### Advantageous Effects of Invention

According to an embodiment of the invention, an electronic device can be provided that detects a detection target while continuously converting electrical energy.

### BRIEF DESCRIPTION OF DRAWINGS

FIG. 1A is an explanatory diagram illustrating a display/input apparatus in an embodiment.

FIG. 1B is an explanatory diagram illustrating the display/input apparatus in the embodiment.

FIG. 1C is a block diagram illustrating the display/input apparatus in the embodiment.

FIG. 2 is a diagram illustrating an operation of the display/input apparatus in the embodiment when a second current is Lo.

FIG. 3 is a diagram illustrating an operation of the display/input apparatus in the embodiment when the second current is Hi.

FIG. 4 is a diagram illustrating an operation of the display/input apparatus in the embodiment when the second current transitions from Hi to Lo.

FIG. 5 is a flowchart showing an operation of the display/input apparatus.

### DESCRIPTION OF EMBODIMENTS

### Summary of Embodiment

An electronic device in the embodiment has a positive electrode arranged below an operation input surface that a detection target approaches or comes into contact with, a negative electrode electrically connected to the positive electrode, a conversion unit that is electrically connected between the positive electrode and the negative electrode and converts electrical energy of a current flowing between the positive electrode and the negative electrode into other type of energy, a current limiting unit that is electrically connected to the negative electrode and limits a current flowing through the negative electrode via the positive electrode and the conversion unit to a current limit value, a first current generation unit that is electrically connected to the positive electrode, and generates and supplies a first current, which is to be the electrical energy of the conversion unit, to the positive electrode, a second current generation unit that is electrically connected to the positive electrode, generates a second current having a voltage greater than that of the first current to charge the positive electrode, and supplies the positive electrode with the second current superimposed on the first current, and a control unit that controls the second current to be superimposed on the first current by controlling the second current generation unit, and determines an approach or contact of the detection target based on a measurement result of a voltage of the positive electrode measured concurrently with the conversion of the electrical energy by the conversion unit.

In the electronic device, a current is constantly supplied to the conversion unit. Therefore, it is possible to detect a detection target while continuously converting electrical energy, as compared to the case where the electrical energy conversion period and the detection period alternate.

### EMBODIMENT

### (General Configuration of a Display/Input Apparatus 1)

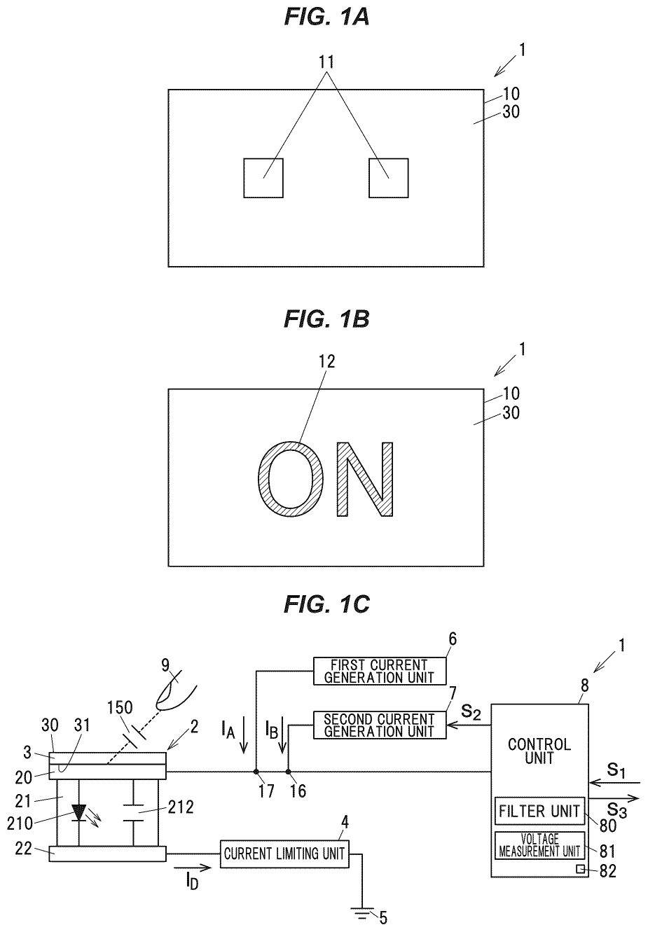

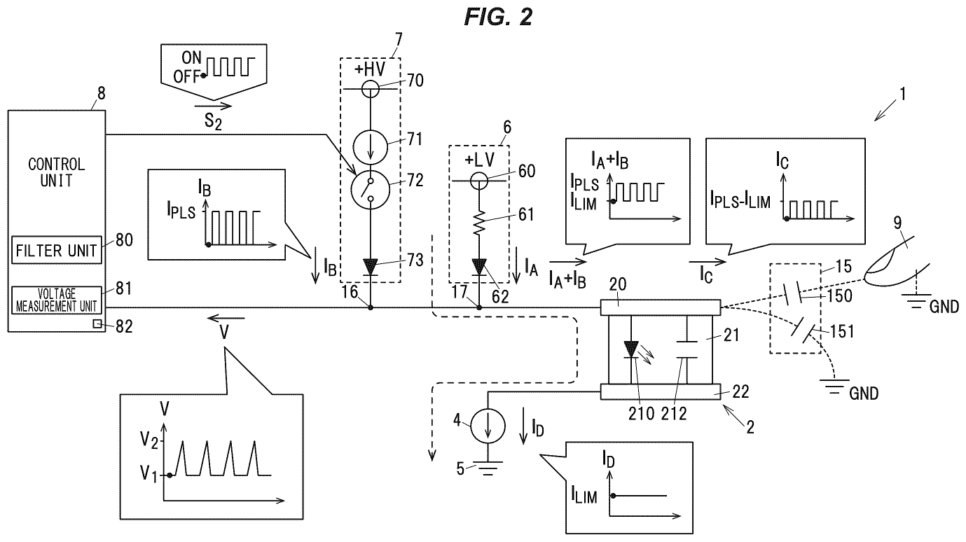

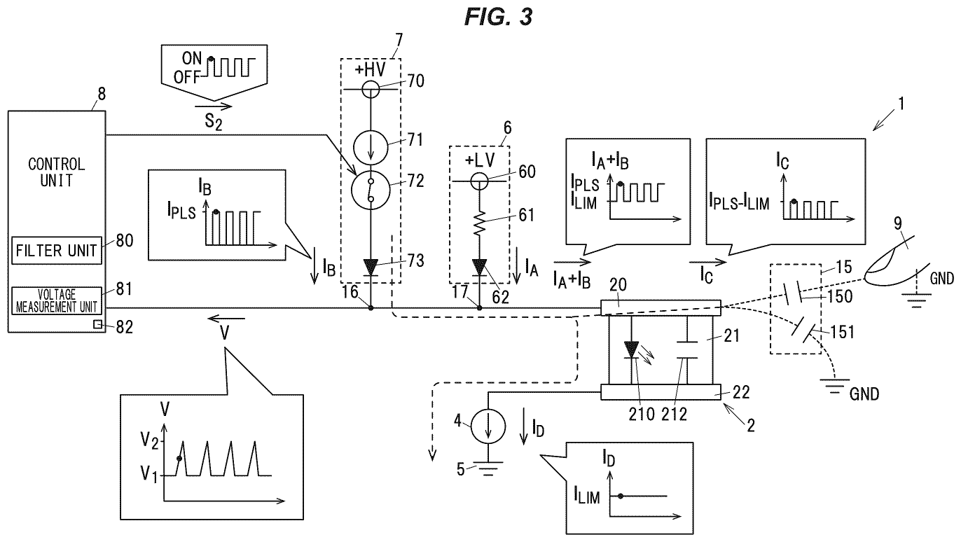

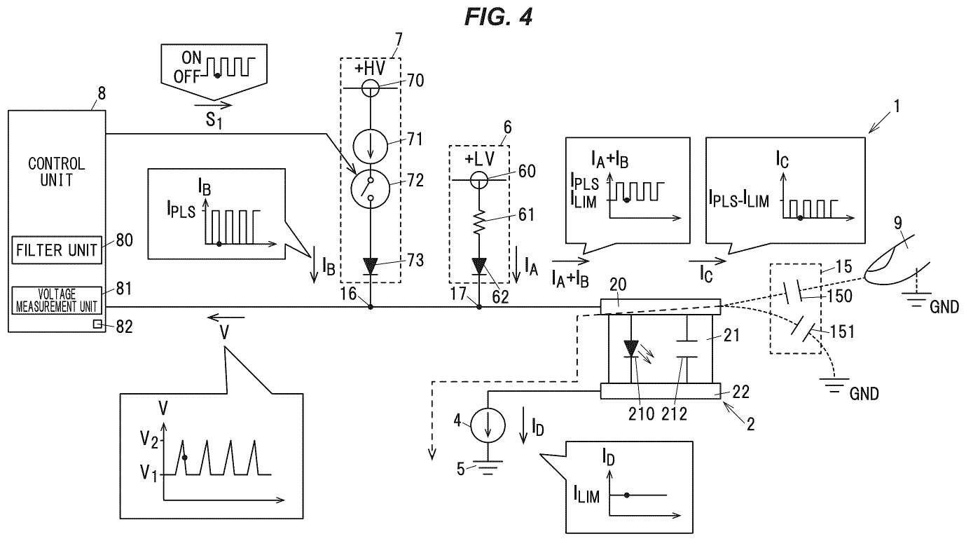

FIG. 1A and FIG. 1B are explanatory diagrams illustrating a display/input apparatus in an embodiment, and FIG. 1C is a block diagram illustrating the display/input apparatus in the embodiment. FIG. 2 is a diagram illustrating an operation of the display/input apparatus in the embodiment when a second current is Lo. FIG. 3 is a diagram illustrating an operation of the display/input apparatus in the embodiment when the second current is Hi. FIG. 4 is a diagram illustrating an operation of the display/input apparatus in the embodiment when the second current transitions from Hi to Lo.

FIGS. 2 to 4 show simplified graphs of a control signal S₂, a second current I_{B}, a first current I_{A}+the second current I_{B} (I_{A}+I_{B}), a current I_{C}, a current I_{D} and a measured voltage V. In the graph of the control signal S₂, the horizontal axis represents time and the vertical axis represents voltage value. In the graphs of the second current I_{B}, the first current I_{A}+the second current I_{B}, the current I_{C} and the current I_{D}, the horizontal axis represents time and the vertical axis represents current value. In the graph of the measured voltage V, the horizontal axis represents time and the vertical axis represents voltage value.

In the drawings of the embodiment described below, a scale ratio or shape may be different between the drawings or different from an actual ratio or shape. In addition, in FIGS. 1C to 4, flows of main signal, information and currents are indicated by arrows. Furthermore, “A-B” indicating the numerical range, etc. shall be used to mean “not less than A and not more than B”.

As an example, the display/input apparatus 1 as an electronic device is mounted on a vehicle. As an example, this display/input apparatus 1 includes plural organic EL elements 2 (described later) and has a display function of serving as a display unit of an in-vehicle device in a vehicle to show a display image 10 related to the in-vehicle device as shown in FIG. 1A, and a function of receiving operation inputs on icons 11 displayed as the display image 10. As an example, this display/input apparatus 1 has a function of showing the display image 10 based on display image information S₁ which is information of image to be displayed, as shown in FIG. 1C.

The operation input is, e.g., a touch operation by an operating finger 9 as a detection target approaching or coming into contact with an operation input surface 30. The approach to the operation input surface 30 here indicates that when the detection target is highly detectable, the detection target is detected in a floating state before coming into contact with the operation input surface 30. In addition, the detection target is the operating finger 9 of a user in the present embodiment, but is not limited thereto and may be a detectable object such as stylus pen.

The in-vehicle device is, as an example, a vehicle control device that controls settings for the entire vehicle and self-driving functions, an air conditioner that adjusts temperature inside the vehicle, a navigation device that shows a map of the current location and guides to a destination, a seat device to control position and inclination of seats, and a music and video playback device to play back music and video, etc.

As an example, the display/input apparatus 1 may be a switch configured to switch a predetermined function between the ON state and the OFF state by a touch operation, as shown in FIG. 1B. This display/input apparatus 1 has a design 12 and displays the design 12 on the operation input surface 30 by using the organic EL elements 2 as lighting. As an example, the design 12 is formed by removing a light-blocking film formed on the operation input surface 30 using a laser, etc. When there are plural locations that receive touch operations, plural designs 12 are provided so as to correspond to the locations.

As shown in FIG. 1C, the display/input apparatus 1 has a positive electrode 20 arranged below the operation input surface 30 that the operating finger 9 approaches or comes into contact with, a negative electrode 22 electrically connected to the positive electrode 20, a conversion unit that is electrically connected between the positive electrode 20 and the negative electrode 22 and converts electrical energy of a current flowing between the positive electrode 20 and the negative electrode 22 into other type of energy, a current limiting unit 4 that is electrically connected to the negative electrode 22 and limits a current flowing through the negative electrode 22 via the positive electrode 20 and the conversion unit to a current limit value I_{LIM}, a first current generation unit 6 that is electrically connected to the positive electrode 20, and generates and supplies the first current I_{A}, which is to be the electrical energy of the conversion unit, to the positive electrode 20, a second current generation unit 7 that is electrically connected to the positive electrode 20, generates the second current I_{B} having a voltage greater than that of the first current I_{A} to charge the positive electrode 20, and supplies the positive electrode 20 with the second current I_{B} superimposed on the first current I_{A}, and a control unit 8 that controls the second current I_{B} to be superimposed on the first current I_{A} by controlling the second current generation unit 7, and determines an approach or contact of the operating finger 9 based on a measurement result of a voltage of the positive electrode 20 measured concurrently with the conversion of the electrical energy by the conversion unit.

The conversion unit in the present embodiment is an organic EL layer 21 that converts electrical energy into light energy, as an example. However, the conversion unit is not limited to the organic EL layer 21, and may be a unit that converts electrical energy into light energy using a configuration different from the organic EL layer 21, or may be a unit that converts electrical energy into thermal energy or mechanical energy, etc. As an example, the conversion unit may be a heating wire that converts electrical energy into thermal energy. Also as an example, the conversion unit may be a motor that converts electrical energy into mechanical energy.

The display/input apparatus 1 mainly adopts the method described below to detect a touch operation by the operating finger 9 while constantly converting electrical energy into light energy.
A method for charging only an electrode-to-GND capacitance 15 (a touch capacitance 150 and a parasitic capacitance 151) while passing the current through the organic EL element 2 In the display/input apparatus 1, in the state of imposing a limit on the current flowing through the organic EL element 2, a current of not less than the limit is supplied to the organic EL element 2 and the electrode-to-GND capacitance 15 is charged. In the display/input apparatus 1, current supply for light emission of the organic EL elements 2 and charging for detecting a touch operation are achieved simultaneously.
A method for constantly supplying a current to the organic EL element 2, and a method for discharging the stored electric charge after detecting a touch operation
   In the display/input apparatus 1, by connecting in parallel the second current generation unit 7, which generates the second current I_{B} which is a pulse current, and the first current generation unit 6, which generates the first current I_{A} having a voltage lower than the maximum voltage of the second current I_{B}, the first current I_{A} from the first current generation unit 6 flows through the organic EL element 2 when the second current I_{B} is Lo.
   In the display/input apparatus 1, immediately after the second current I_{B} is switched from Hi to Lo, the electric charge stored in the electrode-to-GND capacitance 15 flows through the organic EL element 2 and the voltage between the positive electrode 20 and negative electrode 22 of the organic EL element 2 drops to voltage causing inflow from the first current generation unit 6, and the electric charge stored in the electrode-to-GND capacitance 15 is thereby discharged.

As shown in FIG. 2, the electrode-to-GND capacitance 15 shows a capacitance between the positive electrode 20 and the GND, and includes the touch capacitance 150 generated between the GND and the organic EL element 2 through the operating finger 9, and the parasitic capacitance 151 inevitably generated between the GND and the positive electrode 20. This electrode-to-GND capacitance 15 includes all capacitances other than an element capacitance 212 of the organic EL element 2. Here, the voltage of the positive electrode 20 is voltage based on the electrode-to-GND capacitance 15.

### (Configuration of the Organic EL Element 2)

The display/input apparatus 1 includes plural organic EL elements 2. As shown in FIG. 1C, the organic EL element 2 includes the positive electrode 20, the organic EL layer 21 and the negative electrode 22, and is protected by a protective portion 3.

As an example, the positive electrode 20 is a transparent electrode and is formed in a plate shape using ITO (indium tin oxide).

The organic EL layer 21 is a stacked layer composed of a hole transport layer, a light-emitting layer and an electron injection layer, etc., and is sandwiched between the positive electrode 20 and negative electrode 22. The organic EL layer 21 emits light due to the current I_{D} flowing between the positive electrode 20 and the negative electrode 22, and outputs light 211 through the positive electrode 20 and the protective portion 3.

In FIG. 1C, the light-emitting function of the organic EL layer 21 is represented by a light-emitting element 210, and the parasitic capacitance component of the organic EL layer 21 is represented as the element capacitance 212.

The negative electrode 22 is formed in, e.g., a plate shape by a conductive metal or a conductive alloy using of copper or aluminum. The negative electrode 22 is provided in each of the plural organic EL elements 2. The negative electrode 22 is electrically connected to a ground circuit 5, as shown in FIG. 1C.

### (Configuration of the Protective Portion 3)

As an example, the protective portion 3 is formed in a plate shape using a transparent resin such as polycarbonate, or glass. A surface of the protective portion 3 serves as the operation input surface 30. In addition, the plural organic EL elements 2 are arranged on a back surface 31 side of the protective portion 3.

### (Configuration of the Current Limiting Unit 4)

The current limiting unit 4 is electrically connected between the negative electrode 22 and the ground circuit 5. The current limiting unit 4 is configured so as not to allow a current having not less than the predetermined current limit value I_{LIM} to flow.

### (Configuration of the Ground Circuit 5)

The ground circuit 5 is configured as a circuit that defines the reference for the electric potential of the display/input apparatus 1.

### (Configuration of the First Current Generation Unit 6)

The first current generation unit 6 is electrically connected to the organic EL element 2 through positive electrode 17 located between the control unit 8 and the positive electrode 20. The first current generation unit 6 is configured to supply the positive electrode 20 with the first current I_{A} having a current value of at least not less than the current limit value I_{LIM}. As shown in FIG. 2, the first current generation unit 6 includes a constant voltage source 60, a current adjustment resistor 61, and a diode 62 that defines a direction of current flow.

As shown in FIG. 2, the constant voltage source 60 generates a constant voltage LV. The first current generation unit 6 outputs the first current I_{A} based on the current limit value I_{LIM} set by the current limiting unit 4. This constant voltage LV is 8 V, as an example.

### (Configuration of the Second Current Generation Unit 7)

The second current generation unit 7 is electrically connected to the organic EL element 2 through positive electrode 16 located between the control unit 8 and the positive electrode 20. In this regard, the second current generation unit 7 may be connected on the control unit 8 side relative to the first current generation unit 6, i.e., between the control unit 8 and the node 17, or may be connected between the organic EL element 2 and the node 17.

The second current generation unit 7 is configured to generate, under the control of the control unit 8, the second current I_{B} that is a pulse current having Hi as a first state with a high voltage value and Lo as a second state with a voltage value lower than Hi. When a difference between a voltage V₂ of the positive electrode 20 and a voltage V₁ of the current I_{D} having the current limit value I_{LIM}, which are measured when the second current I_{B} is Hi, is equal to or smaller than a predetermined threshold value 82, the control unit 8 determines that the approach or contact of the operating finger 9 has been made. In this regard, since the voltage V₁ is removed as an offset voltage by a filter unit 80 as described later, the voltage V₂ measured by a voltage measurement unit 81 and the threshold value 82 are practically compared.

As shown in FIG. 2, the second current generation unit 7 includes a constant voltage source 70, a constant current unit 71, a switching unit 72 to generate the pulse current, and a diode 73 that defines a direction of current flow.

As shown in FIG. 2, the constant voltage source 70 generates a constant voltage HV. This constant voltage HV is 10 V, as an example. The constant current unit 71 generates the second current I_{B} as a constant current.

The switching unit 72 is electrically connected to the control unit 8 and switches between ON and OFF based on the control signal S₂ output from the control unit 8. As shown in FIGS. 2 and 3, the second current generation unit 7 supplies the second current I_{B} having a current value I_{PLS} to the positive electrode 20 when the switching unit 72 is ON, and the supply of the second current I_{B} is stopped when the switching unit 72 is OFF.

Thus, the second current generation unit 7 generates the second current I_{B}, which is a pulse current, by ON and OFF of the switching unit 72. In the graphs of the second current I_{B} shown in FIGS. 2 to 4, the vertical axis represents current value and the horizontal axis represents time.

### (Configuration of the Control Unit 8)

The control unit 8 is, e.g., a microcomputer composed of a CPU (Central Processing Unit) performing calculation and processing, etc., of the acquired data according to a stored program, and a RAM (Random Access Memory) and a ROM (Read Only Memory) as semiconductor memories, etc. The ROM stores, e.g., a program for operation of the control unit 8. The RAM is used as, e.g., a storage area to temporarily store calculation results, etc. The control unit 8 also has, inside thereof, a means to generate a clock signal and operates based on the clock signal.

The control unit 8 includes the filter unit 80 including a high-pass filter that filters out noise when measuring the voltage of the positive electrode 20, and the voltage measurement unit 81 that measures the voltage of the positive electrode 20 through the filter unit 80. As a modification, the filter unit 80 and the voltage measurement unit 81 may be provided as a circuit outside the control unit 8.

The control unit 8 is an IC (integrated circuit) in which a CPU, a RAM, a ROM, the filter unit 80, and the voltage measurement unit 81 are integrated.

The control unit 8 is configured to perform self-capacitive touch detection, where the electrode-to-GND capacitance 15 is charged and whether or not a touch operation has been performed is determined based on a change in electric potential.

The control unit 8 is configured to periodically turn ON and OFF the switching unit 72 of the second current generation unit 7 by the control signal S₂ in order to make the second current I_{B} a pulse current.

The voltage measurement unit 81 measures the voltage based on the electrode-to-GND capacitance 15, through the positive electrode 20. The voltage V₁ is voltage when limited to the current limit value I_{LIM} by the current limiting unit 4. Meanwhile, the voltage V₂ is voltage when there is no touch operation and the first current I_{A} and the second current I_{B} are supplied to the positive electrode 20. Therefore, ideally, the voltage measurement unit 81 does not need to measure voltages smaller than the voltage V₁ and voltages larger than the voltage V₂.

Here, the voltage which changes depending on with or without the touch operation is the amount of voltage increase (=V₂−V₁) during when the current I_{B} is Hi. Therefore, if V₂ is input to the measured voltage V measured by the voltage measurement unit 81, the sensitivity at the time of touch detection decreases by the voltage V₁ to be the offset voltage. The voltage measurement unit 81 is an ADC (Analog to digital converter) as an example, and is configured to convert the input analog voltage into a digital value with a set number of bits of resolution. Therefore, to increase the resolution, it is ideal to be able to input only the amount of voltage increase to the voltage measurement unit 81 since the voltage which changes depending on with or without the touch operation is the amount of voltage increase during when the current I_{B} is Hi as described above. However, if the voltage V₂ is input as-is to the measured voltage V, the resolution of the voltage measurement unit 81 will be reduced by the offset voltage V₁ relative to the amount of voltage increase (=V₂−V₁). Therefore, the voltage measurement unit 81 is configured to measure voltage from which the voltage V₁, which is an offset voltage, has been removed by the high-pass filter. The resolution is 10 bits, as an example.

For this reason, the control unit 8 includes the filter unit 80 having the high-pass filter to remove the voltage V₁ that is the offset voltage. As a modification, the filter unit 80 may further include a high-cut filter so as not to allow signals with not less than the voltage V₂ to pass through.

When the voltage V₂ measured by the voltage measurement unit 81 is smaller than the predetermined threshold value 82, the control unit 8 determines that a touch operation has been performed. Then, when a touch operation is detected, the control unit 8 generates operation information S₃, which is information of the position, etc. at which the touch operation was detected, and outputs the operation information S₃ to the in-vehicle device electrically connected thereto.

Next, an operation of the display/input apparatus 1 when the second current I_{B} is Lo, is Hi, and changes from Hi to Lo will be described. In the graphs of the control signal S₂, the second current I_{B}, the superimposed first and second currents I_{A} and I_{B}, the current I_{C}, the current I_{D} and the measured voltage V in FIGS. 2 to 4, the values at the present moment are indicated by black dots.
When the second current I_{D} is Lo

The control unit 8 outputs the control signal S₂ to turn OFF the switching unit 72 and thereby stops the supply of the second current I_{B} to the positive electrode 20. Since the switching unit 72 is turned OFF, the second current I_{B} becomes zero as shown in FIG. 2.

The first current I_{A} is constantly supplied to the positive electrode 20. Therefore, the first current I_{A}+the second current I_{B} (I_{A}+I_{B}) is only the first current I_{A}, as indicated by a dotted line in FIG. 2. Of this first current I_{A}, the current I_{D} equivalent of the current limit value I_{LIM} flows to the ground circuit 5 through the positive electrode 20, the organic EL layer 21, the negative electrode 22 and the current limiting unit 4. When the current value of the first current I_{A} is the current limit value I_{LIM}, the first current I_{A} becomes the current I_{D}.

The current I_{C}, which is resulted from subtracting the current limit value I_{LIM} flown through the organic EL element 2 from the current value I_{PLS}, flows through the electrode-to-GND capacitance 15. However, since the first current I_{A} flows through the organic EL element 2 and the second current I_{B} is zero, the current value I_{PLS} is zero and the current I_{C} is zero. That is, the electrode-to-GND capacitance 15 is not charged.

Therefore, when the second current I_{B} is Lo, the voltage measurement unit 81 measures the voltage V₁.
When the second current I_{D} is Hi

The control unit 8 outputs the control signal S₂ to turn the switching unit 72 from OFF to ON and thereby supplies the second current I_{D} to the positive electrode 20. Since the switching unit 72 is turned ON, the second current I_{B} changes from Lo to Hi and its current value changes from zero to the current value I_{PLS}, as shown in FIG. 3.

When the second current I_{B} switches from Lo to Hi, the second current generation unit 7 tries to pass the second current I_{D} through the organic EL element 2, but it is limited by the current limiting unit 4. That is, the current I_{D} flows through the organic EL element 2, but the electric charge of the excess current over the limit is stored in the electrode-to-GND capacitance 15 as indicated by a dotted line in FIG. 3 and the electric potential of the positive electrode 20 starts rising. The electric potential of the positive electrode 20 continues to rise with a slope related to the magnitude of the electrode-to-GND capacitance 15, as shown in the graph of the measured voltage V in FIG. 3.

When the electric potential of the positive electrode 20 becomes not less than the voltage of the first current I_{A} of the first current generation unit 6, the first current I_{A} stops flowing from the first current generation unit 6. That is, when the second current I_{B} is Lo, the current value of the first current I_{A} becomes the current limit value I_{LIM} and the first current I_{A} flows as the current I_{D} through the organic EL element 2. On the other hand, when the second current I_{B} is at Hi, a part of the second current I_{B} flows as the current I_{D} through the organic EL element 2 and also charges the electrode-to-GND capacitance 15.

Therefore, when the second current I_{B} is switched to Hi, the first current I_{A}+the second current I_{B} (I_{A}+I_{B}) has the current value I_{PLS} as shown in FIG. 3. At this time, the voltage measurement unit 81 measures the voltage V₂ as the measured voltage V of the positive electrode 20.

If a touch operation is being performed here, the voltage measurement unit 81 measures the voltage V₂ (>V₁) that is lower than the voltage V₂ at its peak. The control unit 8 compares the measured voltage V₂ with the threshold value 82 and determines whether or not a touch operation has been performed.
When the second current I_{B} switches from Hi to Lo

The control unit 8 outputs the control signal S₂ to turn OFF the switching unit 72 and thereby stops the supply of the second current I_{D} to the positive electrode 20. Since the switching unit 72 is turned OFF, the second current I_{D} switches from Hi to Lo as shown in FIG. 4.

The electric charge stored in the electrode-to-GND capacitance 15 flows to the organic EL element 2 as indicated by a dotted line in FIG. 4, and the electric potential based on the stored electric charge starts decreasing. After the electric potential drops to near the voltage of the first current generation unit 6, the first current I_{A} starts flowing from the first current generation unit 6 again and rises to the current limit value I_{LIM} limited by the current limiting unit 4.

In the display/input apparatus 1, switching the second current I_{B} from Hi to Lo allows the electric charge stored in the electrode-to-GND capacitance 15 to flow to the ground circuit 5 through the organic EL element 2 and to be discharged.

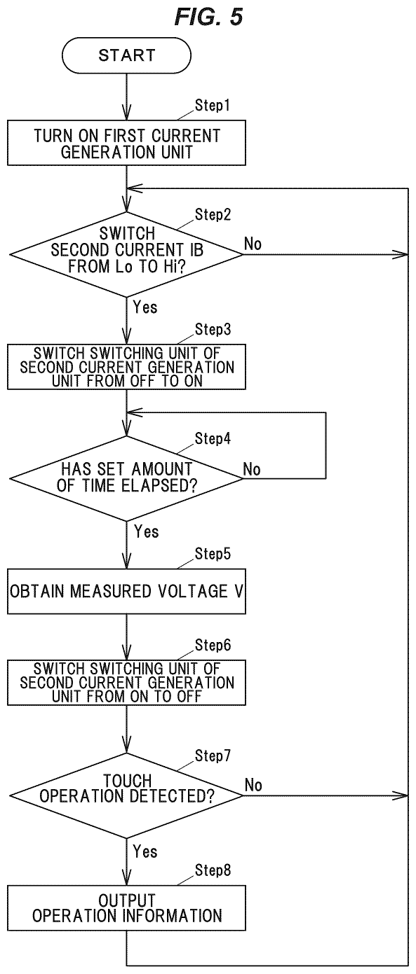

Next, an example of the operation of the display/input apparatus 1 in the present embodiment will be described according to the flowchart in FIG. 5. The second current I_{B} when the display/input apparatus 1 is powered on is assumed to be Lo.

### (Operation)

When the power is turned on, the control unit 8 of the display/input apparatus 1 turns ON the first current generation unit 6 to supply the first current I_{A} to the positive electrode 20 (Step 1).

The control unit 8 starts measuring time and determines whether or not to switch the second current I_{B} from Lo to Hi. When it is “Yes” in Step 2, i.e., when it is time to switch the second current I_{B} from Lo to Hi (Step 2: Yes), the control unit 8 outputs the control signal S₂ to the switching unit 72 to switch the switching unit 72 from OFF to ON, and thereby switches the second current I_{B} from Lo to Hi (Step 3).

The control unit 8 monitors whether a set amount of time, which is set as a period sufficient to charge the electrode-to-GND capacitance 15 since switching of the second current I_{B} from Lo to Hi, has elapsed. When it is “Yes” in Step 4, i.e., when the set amount of time has elapsed (Step 4: Yes), the control unit 8 controls the voltage measurement unit 81 and obtains the measured voltage V (Step 5).

After obtaining the measured voltage V, the control unit 8 outputs the control signal S₂ to the switching unit 72 to switch the switching unit 72 from ON to OFF, and thereby switches the second current I_{B} from Hi to Lo (Step 6).

The control unit 8 determines whether or not a touch operation has been performed, based on the measurement result of the voltage measurement unit 81. When a touch operation is detected (Step 7: Yes), the control unit 8 outputs the operation information S₃ to the in-vehicle device electrically connected thereto based on the determined touch operation (Step 8), and proceeds to Step 2.

Here, when no touch operation is detected in Step 7 (Step 7: No) the control unit 8 proceeds to Step 2.

### Effects of the Embodiment

The display/input apparatus 1 can detect a detection target while continuously converting electrical energy. In particular, the display/input apparatus 1 can detect the detection target while converting electrical energy into light energy by the organic EL layer 21 and thus can detect the detection target while continuously performing display or lighting by the organic EL elements 2, as compared to the case where the electrical energy conversion period and the detection period alternate.

When the electrical energy conversion period and the detection period alternate, the time allocated to each period is halved, resulting in a decrease in brightness and detection accuracy. However, since the display/input apparatus 1 detects the detection target while continuously performing display or lighting, it is possible to take a longer detection period and possible to have higher brightness and improved detection accuracy.

Since the display/input apparatus 1 does not require detection electrodes to detect touch operations, it is possible to simplify the manufacturing process and also reduce the thickness as compared to the case where detection electrodes are provided additionally.

The display/input apparatus 1 can output the light 211 from the organic EL element 2 without passing through detection electrodes for touch detection. Therefore, the transmittance is improved, light can be used efficiently and high brightness can be easily achieved, as compared to the case where detection electrodes are provided additionally.

The display/input apparatus 1 in the embodiment and modifications described above may be partially realized by, e.g., a program executed by a computer, an ASIC (Application Specific Integrated Circuit), and an FPGA (Field Programmable Gate Array), etc., depending on the application.

Although some embodiment and modifications of the invention have been described, these embodiment and modifications are merely examples and the invention according to claims is not to be limited thereto. These new embodiment and modifications may be implemented in various other forms, and various omissions, substitutions and changes, etc., can be made without departing from the gist of the invention. In addition, not all combinations of the features described in the embodiment and modifications are necessary to solve the problem of the invention. Further, these embodiment and modifications are included within the scope and gist of the invention and also within the invention described in the claims and the range of equivalency.

### REFERENCE SIGNS LIST

1 DISPLAY/INPUT APPARATUS
4 CURRENT LIMITING UNIT
6 FIRST CURRENT GENERATION UNIT
7 SECOND CURRENT GENERATION UNIT
8 CONTROL UNIT
20 POSITIVE ELECTRODE
21 ORGANIC EL LAYER
22 NEGATIVE ELECTRODE
30 OPERATION INPUT SURFACE
80 FILTER UNIT
81 VOLTAGE MEASUREMENT UNIT

1. An electronic device, comprising:
a positive electrode arranged below an operation input surface that a detection target approaches or contacts;
a negative electrode electrically connected to the positive electrode;
a conversion unit that is electrically connected between the positive electrode and the negative electrode and converts electrical energy of a current flowing between the positive electrode and the negative electrode into other type of energy;
a current limiting unit that is electrically connected to the negative electrode and limits a current flowing through the negative electrode via the positive electrode and the conversion unit to a current limit value;
a first current generation unit that is electrically connected to the positive electrode, and generates and supplies a first current, which is to be the electrical energy of the conversion unit, to the positive electrode;
a second current generation unit that is electrically connected to the positive electrode, generates a second current having a voltage greater than that of the first current to charge the positive electrode, and supplies the positive electrode with the second current superimposed on the first current; and
a control unit that controls the second current to be superimposed on the first current by controlling the second current generation unit, and determines the approach or contact of the detection target based on a measurement result of a voltage of the positive electrode measured concurrently with the conversion of the electrical energy by the conversion unit.

2. The electronic device according to claim 1, wherein the operation input surface is provided on a surface of a protective portion that protects the positive electrode.

3. The electronic device according to claim 2, wherein the first current generation unit supplies the positive electrode with the first current having a current value of at least not less than the current limit value.

4. The electronic device according to claim 3, wherein the first current generation unit comprises a constant voltage source, a current adjustment resistor, and a diode that defines a direction of current flow.

5. The electronic device according to claim 4, wherein the second current generation unit generates, under the control of the control unit, the second current that is a pulse current having a first state with a high voltage value and a second state with a voltage value lower than the first state, and wherein when a difference between the voltage of the positive electrode and voltage of a current having the current limit value, which are measured when the second current is in the first state, is equal to or smaller than a predetermined threshold value, the control unit determines that the approach or contact of the detection target has been made.

6. The electronic device according to claim 5, wherein the second current generation unit comprises a constant voltage source, a constant current unit, a switching unit to generate the pulse current, and a diode that defines a direction of current flow.

7. The electronic device according to claim 6, wherein the control unit comprises a filter unit comprising a high-pass filter that filters out noise when measuring the voltage of the positive electrode, and a voltage measurement unit that measures the voltage of the positive electrode through the filter unit.

8. The electronic device according to claim 7, wherein the filter unit further comprises a high-cut filter.

9. The electronic device according to claim 1, wherein the conversion unit comprises an organic EL layer that converts the electrical energy into light energy.

10. The electronic device according to claim 1, wherein the conversion unit comprises a heating wire that converts the electrical energy into thermal energy, or a motor that converts the electrical energy into mechanical energy.
